(19) United States
(12) Patent Application Publication
(10) Pub. No.: US 2021/0104279 A1
(43) Pub. Date: Apr. 8, 2021

(54) SINGLE-GATE MULTIPLE-TIME PROGRAMMING NON-VOLATILE MEMORY ARRAY AND OPERATING METHOD THEREOF

(71) Applicant: YIELD MICROELECTRONICS CORP., Chu-Pei City (TW)

(72) Inventors: CHENG-YING WU, CHU-PEI CITY (TW); WEI-TUNG LO, CHU-PEI CITY (TW); WEN-CHIEN HUANG, CHU-PEI CITY (TW)

(21) Appl. No.: 16/708,888

(22) Filed: Dec. 10, 2019

(30) Foreign Application Priority Data
Oct. 8, 2019 (TW) 108136332

(51) Int. Cl. G11C 16/10; H01L 27/11521; G11C 16/04; G11C 16/24; G11C 16/14

(52) U.S. Cl. CPC G11C 16/10; H01L 27/11521; G11C 16/14; G11C 16/24; G11C 16/0416

(57) ABSTRACT

A single-gate multiple-time programming non-volatile memory array and an operating method thereof are provided, wherein the single-gate non-volatile memory array has bit lines, common source line groups, and sub-memory arrays. In each sub-memory array, a first memory cell is connected with a first bit line and one common source line of a first common source line group. The second memory cell is connected with the first bit line and the other common source line of the first common source line group. The first and second memory cells are operation memory cells and symmetrically arranged at the same side of the first bit line. The minimum control voltages and elements during operating are involved to greatly reduce the area, control lines and the cost thereof.

This application claims priority for Taiwan patent application no. 108136332 filed on Oct. 8, 2019, the content of which is incorporated by reference in its entirely.

### BACKGROUND OF THE INVENTION

### Field of the Invention

The present invention relates to a memory array, particularly to a single-gate multiple-time programming non-volatile memory array and an operating method thereof.

### Description of the Related Art

The CMOS (Complementary Metal Oxide Semiconductor) process has been a normal fabrication method for ASIC (Application Specific Integrated Circuit). Flash memories and EEPROM (Electrically Erasable Programmable Read Only Memory), which features electric programmability and erasability and would not lose its memory after power is turned off, has been widely used in electronic products in the computer and information age.

A non-volatile memory is programmed via keeping charges to vary the gate voltage of the transistor thereof, or not keeping charges to preserve the gate voltage of the transistor. For a non-volatile memory, an erase operation is used to eliminate all the charges kept in the non-volatile memory and restore all the transistors to have the original gate voltages. The flash memory architecture has advantages of small size and low cost. However, the flash memory architecture does not allow erasing or programming a single one-bit memory cell but allows erasing or programming a block of the memory. Therefore, the flash memory architecture is inconvenient in application. The EEPROM architecture supports a “byte write” function. Thus, the EEPROM architecture is more convenient than the flash memory architecture. However, in the conventional EEPROM structure, there are many kinds of control voltages and many memory elements. Therefore, EEPROM occupies larger area than the flash memory. Besides, in bit erasing of EEPROM, the transistors at the unselected positions must be separated. Thus, the cost of using EEPROM is increased.

### SUMMARY OF THE INVENTION

In order to overcome the abovementioned problems of the conventional technology, the present invention provides a single-gate multiple-time programming non-volatile memory array, and further provides an operating method based on the architecture, so as to perform the bytes writing, erasing and reading operations at the same time.

To achieve the abovementioned objectives, the present invention provides a single-gate multiple-time programming non-volatile memory array, which comprises a plurality of parallel bit lines, a plurality of parallel common source lines and a plurality of sub-memory arrays. The bit lines comprise a first bit line. The common source lines are vertical to said bit lines and divided into a plurality of common source, line groups including a first common source line group, and the first common source line group includes a first common source line and a second common source line. Each sub-memory array is connected with one bit line and one common source line group, and each sub-memory array includes a first memory cell and a second memory cell. The first memory cell is connected with the first bit line and the first common source line. The second memory cell is connected with the first bit line and the second common source line. The first memory cell and the second memory cell are symmetrically arranged at an identical side of the first bit line.

Each of the first and second memory cells functions as an operation memory cell. In selecting one of the operation memory cells as a selected memory cell in carrying out its operations, the operation memory cells, that are connected to the same bit line connecting to the selected memory cell, but not connected to the same common source line connecting to the selected memory cell, are referred to as a plurality of common bit line memory cells; the operation memory cells, that are connected to the same bit line connecting to the selected memory cell, are referred to as a plurality of common word memory cells; and the rest of the operation memory cells are referred to a plurality of unselected memory cells.

The first and second memory cells may both contain an N-type field effect transistor located in a P-type well region or in a P-type substrate. Or, alternatively, they may both contain a P-type field effect transistor located in an N-type well region or in an N-type substrate.

In case of the memory having an N-type field effect transistor, when in operating, performing the following steps are required: applying a substrate voltage V_{subp} on a P-type well region or a P-type substrate connecting, to a selected memory cell; applying a first bit voltage V_{b1}, a first common source voltage Vₛ₁ respectively on a bit line and a common source line, both connecting to each selected memory cell; and applying a second bit voltage V_{b2} and a second common source voltage Vₛ₂ respectively on the bit line and the common source line connecting to each unselected memory cell.

As such, in erasing data from the selected memory cell, following conditions have to be satisfied: V_{subp} is grounded (0), V_{b1} is grounded (0), and Vₛ₁=HV (High Voltage); in writing data into the selected memory cell, the following conditions have to be satisfied: V_{subp} is grounded (0), V_{b1}=MV (medium voltage), and Vₛ₁ is grounded (0); in reading data from the selected memory cell, following conditions have to be satisfied: V_{subp} is grounded (0), V_{b1}=LV (Low Voltage)−2V, and Vₛ₁ is grounded (0); in erasing data from the unselected memory cells, the following conditions have to be satisfied: V_{subp} is grounded (0), V_{b2} is grounded (0), and Vₛ₂=LV (Low Voltage)−2V; in writing data from the unselected memory cells, the following conditions have to be satisfied: V_{subp} is grounded (0), V_{b2} is grounded (0), and Vₛ₂=LV (Low Voltage)−2V; and in reading data from the unselected memory cells, the following conditions have to be satisfied: V_{subp} is grounded (0), V_{b2} is grounded (0), and Vₛ₂=LV (Low Voltage)−2V.

In case of the memory having a P-type field effect transistor, when in operating, performing the following steps are required: applying a substrate voltage V_{subn} on an N-type well region or an N-type substrate connecting to a selected memory cell. As such, in case of the memory having a P-type field effect transistor, in erasing data from the selected memory cell, following conditions have to be satisfied: V_{subn}=HV (High Voltage), V_{b1}=HV (High Voltage), and Vₛ₁ is grounded (0); in writing data into the selected memory cell, the following conditions have to be satisfied: V_{subn}=HV (High Voltage), V_{b1}−HV is grounded (0), and Vₛ₁=MV (medium voltage)−6V; in reading data from the selected memory cell, following conditions have to be satisfied; V_{subn}=HV (High Voltage), V_{b1} is grounded (0), and Vₛ₁=LV (Low Voltage)−2V; in erasing data from the unselected memory cells, the following conditions have to be satisfied: V_{subn}=HV (High Voltage), V_{b2}=LV (Low Voltage)−2V, and Vₛ₂=LV (Low Voltage) or grounded (0); in writing data from the unselected memory cells, the following conditions have to be satisfied: V_{subn}=HV (High Voltage), V_{b2}=LV (Low Voltage)−2V and Vₛ₂=LV (Low Voltage) or grounded (0); and in reading data from the unselected memory cells, the following conditions have to be satisfied: V_{subn}=HV (High Voltage), V_{b2}=LV (Low Voltage)−2V, and Vₛ₂=LV (Low Voltage) or grounded (0).

Further, the first memory cell and the second memory cell both include a transistor and a capacitor structure, wherein the transistor and the capacitor structure are disposed in the semiconductor substrate. The transistor comprises a first dielectric layer, a first conduction gate and two highly-conductive ion-doped regions, the first dielectric layer is disposed on the semiconductor substrate, the first conduction gate is stacked on the surface of the first dielectric layer, and the ion-doped regions are respectively disposed at two sides of the first conduction gate and the first dielectric layer to function as a source and a drain and disposed in the semiconductor substrate, wherein the source and the drain have different widths. The edge of the drain is utilized to serve as a capacitor to form the capacitor structure and control a floating gate. A lightly-doped region is located between the drain and the floating gate, and the lightly-doped region and the ion-doped regions are doped with the same type of ions, jointly functioning as a single floating gate of the first memory cell and the second memory cell.

Since the source and the drain of the first and second memory cells are designed to have different widths, the edge of the drain is used to control the floating gate. Thereby, the minimum control voltages and elements during operating are involved to reduce the whole area. Comparing with a conventional single-gate programming non-volatile memory having high cost due to complicated control, the present invention can greatly reduce the amount of the control lines and costs of the non-volatile memory resulting from the simple operations and the least elements.

Below, the embodiments are described in detail in cooperation with the drawings to make easily understood the technical contents, characteristics and accomplishments of the present invention.

### BRIEF DESCRIPTION OF THE DRAWINGS

FIG. 1 schematically shows the circuit of a single-gate multiple-time programming non-volatile memory array according to an embodiment of the present invention;

FIG. 2 schematically shows the circuit of a sub-memory array of a single-gate multiple-time programming non-volatile memory array according to the embodiment of the present invention;

FIG. 3 schematically shows a sectional view of an N-type FET and a capacitor of a memory cell according to one embodiment of the present invention; and

FIG. 4 schematically shows a sectional view of a P-type FET and a capacitor of a memory cell according to one embodiment of the present invention.

### DETAILED DESCRIPTION OF THE INVENTION

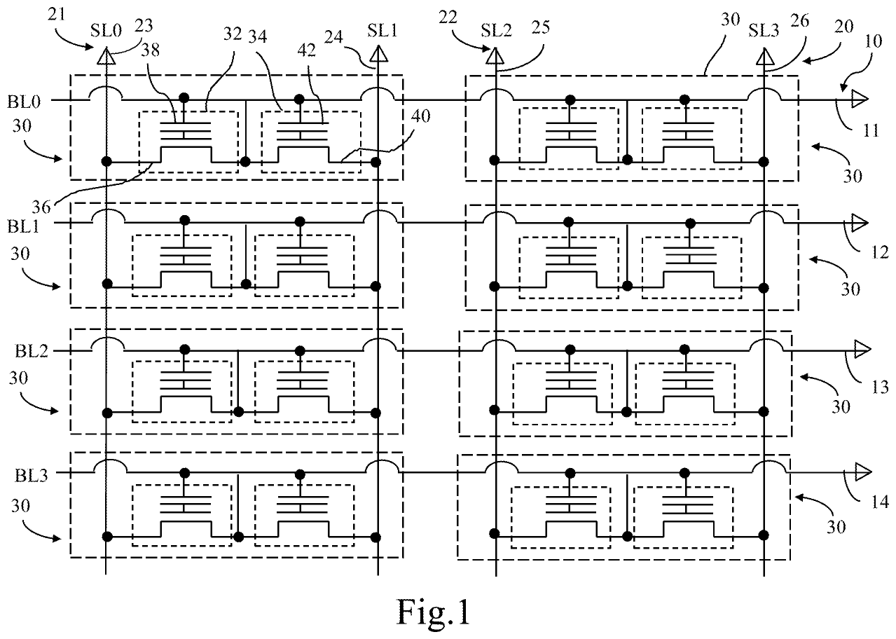

Refer to FIG. 1 for an embodiment of the present invention. The single-gate multiple-time programming non-volatile memory array of the embodiment comprises a plurality of parallel bit lines 10, a plurality of parallel common source lines 20, and a plurality of sub-memory arrays 30. The bit lines 10 include a first bit line 11, a second bit line 12, a third bit line 13, and a fourth bit line 14. The common source lines 20 are vertical to the bit lines 10 and divided into a plurality of common source line groups 20 including a first common source line group 21 and a second common source line group 22. The first common source line group 21 includes a first common source line 23 and a second common source line 24, and the second common source line group 22 including a third common source line 25 and a fourth common source line 26. The bit lines 10 and the common source lines 20 are connected with sub-memory arrays 30, each containing 2×1 pieces of memory cells. Each sub-memory array 30 is connected with one bit line 10 and one common source line group 20. The connections of the sub-memory arrays 30 with the bit lines 10 and the common source lines 20 are similar. The common characteristics of the connections are described below.

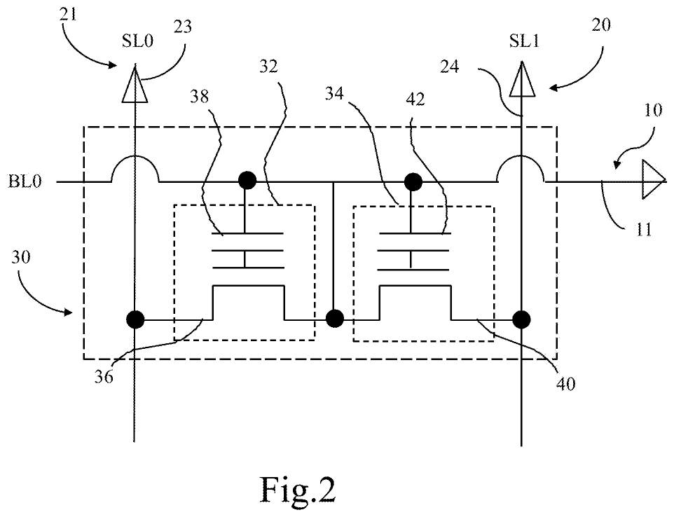

Please refer to FIG. 2. Each sub-memory array 30 includes a first memory cell 32 and a second memory cell 34. The first memory cell 32 is connected with the first bit line 11 and the first common source line 23 of the first common source line group 21. The second memory cell 34 is connected with the first bit line 11 and the second common source line 24 of the first common source line group 21. The first memory cell 32 and the second memory cell 34 are symmetrically arranged at an identical side of the first bit line 11.

The first memory cell 32 further includes an FET 36 (field effect transistor) and a capacitor 38. The FET 36 has a floating gate, a drain connected with the first common source line 23 of the first common source line group 21, and a source connected with the first bit line 11. The edge of the drain is connected with the floating gate. One terminal of the capacitor 38 is connected with the floating gate of the FET 36, and the other terminal of the, capacitor 38 is connected with the first bit line 11 to receive a bias from the first bit line 11. The FET 36 receives a bias from the first bit line 11 and receives a bias from the first common source line 23 so as to write data into, erase or read data in the floating gate.

The second memory cell 34 further includes an FET 40 and a capacitor 42. The FET 40 has a floating gate, a drain connected with the second common source line 24 of the first common source line group 21, and a source connected with the first bit line 11. The edge of the drain s connected with the floating gate. One terminal of the capacitor 42 is connected with the floating gate of the FET 40, and the other terminal of the capacitor 42 is connected with the first bit line 11 to receive a bias from the first bit line 11. The FET 40 receives a bias from the first bit line 11 and receives a bias from the second common source line 24 so as to write data into, erase or read data in the floating gate.

Both the FET 36 and the FET 40 are N-type FETs built in, a P-type substrate or a P-type well region. Alternatively, both the FET 36 and the FET 40 are P-type FETs built in an N-type substrate or an N-type well region. The method for operating a single-gate multiple-time programming non-volatile memory array has different sub-embodiments with respect to the types of FETs. Below the sub-embodiment corresponding to the N-type FETs 36 and 40 is described firstly. In order to understand the ways of operations, the names of various memory cells are first clearly defined as follows.

Both the abovementioned first and second memory cells 32 and 34 are operation memory cells, and one of the operation memory cells can be selected as the selected memory cell to proceed with the operations as required. As to the operation memory cells, that are connected to the same bit line 10 connecting to the selected memory cell, but not connected to the same common source line 20 connecting to the selected memory cell, are referred to as a plurality of common bit memory cells. The operation memory cells, which are connected to the same bit line 10 connecting to the selected memory cell, are referred to as a plurality of common word memory cells. The rest of the operation memory cells are referred to as a plurality of unselected memory cells.

In the following, the operations of the embodiment are described, such that m this way of operation, other unselected memory cells will not be affected, thus operation is related to a specific single memory cell.

When in operating, performing the following steps are required: applying a substrate voltage V_{subp} on a P-type well region or P-type substrate connecting to a selected memory cell; applying a first bit voltage V_{b1}, a first common source voltage Vₛ₁ on a bit line 14, and a common source line 20, both connecting to a selected memory cell; applying a second common source voltage Vₛ₂ on a common source line 20, connecting to each common bit memory cell; applying a second bit voltage V_{b2}, a first common source voltage Vₛ₁ on a bit line 10, and a common source line 20, both connecting to each common word memory cell; and applying a second bit voltage V_{b2}, and a second common source voltage Vₛ₂ on the bit line 10, and the common source line 20, both connecting to an unselected memory cell.

In erasing data from the selected memory cell, the following conditions have to be satisfied: V_{subp} is grounded (0), V_{b1} is grounded (0), and Vₛ₁=HV (High Voltage).

In writing data into the selected memory cell, the following conditions have to be satisfied: V_{subp} is grounded (0), V_{b1}=MV (medium voltage), and Vₛ₁ is grounded (0).

In reading data from the selected memory cell, following conditions are to be satisfied: V_{subp} is grounded (0), V_{b1}=LV (Low Voltage)−2V, and Vₛ₁ is grounded (0).

In erasing data from the unselected memory cells, the following conditions have to be satisfied: V_{subp} is grounded (0), V_{b2} is grounded (0), and Vₛ₂=LV (Low Voltage)−2V.

In writing data from the unselected memory cells, the following conditions have to be satisfied: V_{subp} is grounded (0), V_{b2} is grounded (0), and Vₛ₂=LV (Low Voltage)−2V.

In reading data from the, unselected memory cells, the following conditions have to be satisfied: V_{subp} is grounded (0), V_{b2} is grounded (0), and Vₛ₂=LV (Low Voltage)−2V.

While the FET 36 and the FET 40 are P-type FETs, applying a substrate voltage V_{subn} on an N-type well region or an N-type substrate connecting to a selected memory cell.

In erasing data from the selected memory cell, following conditions have to be satisfied: V_{subn}=HV (High Voltage), V_{b1}=HV (High Voltage), and Vₛ₁ is grounded (0).

In writing data into the selected memory cell, the following conditions have to be satisfied: V_{subn}=HV (High Voltage), V_{b1} is grounded (0), and Vₛ₁=MV (medium voltage)−6V.

In reading data from the selected memory cell, following conditions are to be satisfied: V_{subn}=HV (High Voltage), V_{b1} is grounded (0), and Vₛ₁=LV (Low Voltage)−2V.

In erasing data from the unselected memory cells, the following conditions have to be satisfied: V_{subn}=HV (High Voltage), V_{b2}=LV (Low Voltage)−2V, and Vₛ₂=LV (Low Voltage) or grounded (0).

In writing data from the unselected memory cells, the following conditions have to be satisfied: V_{subn}=HV (High Voltage), V_{b2}=LV (Low Voltage)−2V, and Vₛ₂=LV (Low Voltage) or grounded (0).

In reading data from the unselected memory cells, the following conditions have to be satisfied: V_{subn}=HV (High Voltage), V_{b2}=LV (Low Voltage)−2V, and Vₛ₂=LV (Low Voltage) or grounded (0).

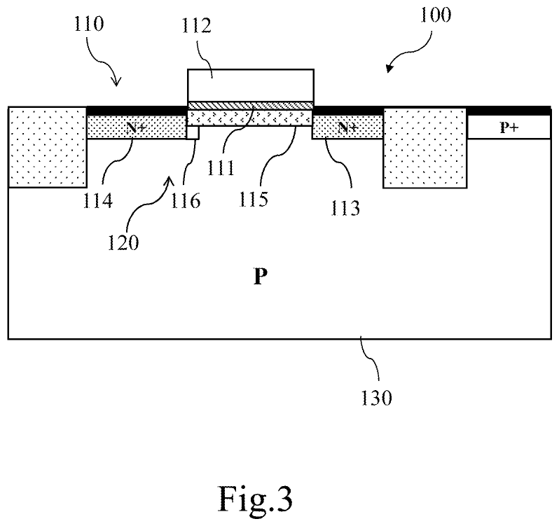

In the following, a cross section view of a structure, of field effect transistors 36 and 40 and capacitors 38 and 42 of the present invention is described. In this case, an N-type FET is taken as an example for explanation. As shown in FIG. 3, an N-type FET 110 and an N-type capacitor 120 are disposed in a P-type semiconductor substrate 130 or a semiconductor substrate with a P-type well. The N-type FET 110 comprises a first dielectric layer 111 disposed on the P-type semiconductor substrate 130, a first conduction gate 112 stacked on the first dielectric layer 111, and two ion-doped regions disposed in the P-type semiconductor substrate 130 to respectively function as a source 113 and a drain 114, wherein a channel 115 is formed between the source 113 and the drain 114. The source 113 and the drain 114 have different widths. The N-type capacitor 120 uses the edge of the drain 114 to control a floating gate, jointly functioning as a single floating gate of the memory cell 100. The N-type capacitor 120 has a lightly-doped region 116 between the drain 114 and the floating gate, and the ion-doped regions and the lightly-doped region 116 are N-type ion-doped regions.

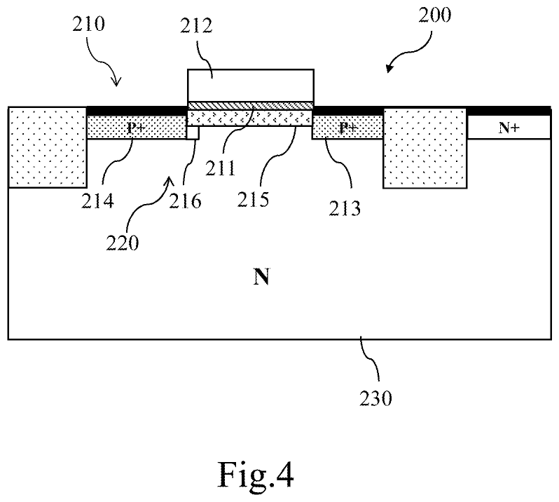

Similarly, in the following, a cross section view of a structure of field effect transistors 36 and 40 and capacitors 38 and 42 of the present invention is described. In this case, a P-type field effect transistor is taken as an example for explanation. As shown in FIG. 4, a P-type FET 210 and a P-type capacitor 220 are disposed in a N-type semiconductor substrate 230 or a semiconductor substrate with a N-type well. The P-type FET 210 comprises a first dielectric layer 211 disposed on the N-type semiconductor substrate 230, a first conduction gate 212 stacked on the first dielectric layer 211, and two ion-doped regions disposed in the N-type semiconductor substrate 230 to respectively function as a source 213 and, a drain 214, wherein a channel 215 is formed between the source 213 and the drain 214. The source 213 and the drain 214 have different widths. The P-type capacitor 220 uses the edge of the drain 214 to control a floating gate, jointly functioning as a single floating gate of the memory cell 200. The P-type capacitor 220 has a lightly-doped region 216 between the drain 214 and the floating gate, and the ion-doped regions and the lightly-doped region 216 are P-type ion-doped regions.

In the above embodiment, the edge of the drain 114 and 214 of the field effect transistors 36 and 40 is in the middle of the floating gate. The widths of the source 113 and 213 and the drain 114 and 214 are the side lengths along a horizontal axis direction (i.e. the direction parallel to the direction from the source 113 and 213 to the drain 114 and 214, respectively), as shown in FIGS. 3-4. It is shown that the width of the drain 114 and 214 are respectively larger than the width of the source 113 and 213 in the embodiment.

Summing up the above, the single-gate multiple-time programming non-volatile memory array and an operating method thereof according to the present invention is capable of providing a single-gate multiple-time programming non-volatile memory array structure of smaller area at lower cost. Moreover, the present invention can greatly reduce the lengths of control lines, areas and production costs of the non-volatile memory resulting from simple operations and the least elements and the least control voltages.

The embodiments described above are only to exemplify the present invention but not to limit the scope of the present invention. Therefore, any equivalent modification or variation according to the shapes. structures, features, or spirit disclosed by the present invention is to be also included within the scope of the present invention.

What is claimed is:

1. A single-gate multiple-time programming non-volatile memory array comprising:
a plurality of parallel bit lines having a first bit line;
a plurality of parallel common source lines, being vertical to said bit lines and divided into a plurality of common source line groups including a first common source line group, wherein said first common source line group includes a first common source line and a second common source line; and
a plurality of sub-memory arrays, each connected with one of said bit lines and one of said common source line groups, and each said sub-memory array includes:
a first memory cell connected with said first bit line and said first common source line; and
a second memory cell connected with said first bit line and said second common source line, wherein said first memory cell and said second memory cell are symmetrically arranged at an identical side of said first bit line.

2. The single-gate multiple-time programming non-volatile memory array according to claim 1, wherein said first memory cell comprising:
a transistor disposed in a semiconductor substrate and having a first dielectric layer, a first conduction gate and a plurality of ion-doped regions, wherein said first dielectric layer is disposed on a surface of said semiconductor substrate, said first conduction gate is stacked on said first dielectric layer, and said ion-doped regions are respectively disposed at two sides of said first conduction gate to function as a source and a drain and disposed in said semiconductor substrate, wherein the source and the drain have different widths; and
a capacitor disposed on said semiconductor substrate, wherein an edge of the, drain is served as a capacitor to control a floating gate and the capacitor includes a lightly-doped region between the drain and the floating gate, and said lightly-doped region and said ion-doped regions are doped with the same type of ions, and forming a single floating gate of said first memory cell.

3. The single-gate multiple-time programming non-volatile memory array according to claim 2, wherein said transistor structure is an N-type field-effect transistor (FET) or a P-type FET.

4. The single-gate multiple-time programming non-volatile memory array according to claim 1, wherein said second memory cell comprising:
a transistor disposed in a semiconductor substrate and having a first dielectric layer, a first conduction gate and a plurality of ion-doped regions, wherein said first dielectric layer is disposed on a surface of said semiconductor substrate, said first conduction gate is stacked on said first dielectric layer, and said ion-doped regions are respectively disposed at two sides of said first conduction gate to function as a source and a drain and disposed in said semiconductor substrate, wherein the source and the drain have different widths; and
a capacitor disposed on said semiconductor substrate, wherein an edge of the drain is served as a capacitor to control a floating gate and the capacitor includes a lightly-doped region between the drain and the floating gate, and said lightly-doped region and said ion-doped regions are doped with the same type of ions, and forming a single floating gate of said second memory cell.

5. The single-gate multiple-time programming non-volatile memory array according to claim 4, wherein said transistor structure is an N-type FET or a P-type FET.

6. An operating method of a single-gate multiple-time programming non-volatile memory array, therein said non-volatile memory array includes a plurality of parallel bit lines having a first bit line, a plurality of parallel common source lines, being vertical to said bit lines and divided into a plurality of common source line groups including a first common source line group, including a first common source line and a second common source line, and a plurality of sub-memory arrays, each being connected with one of said bit line and one of said common source line group, and wherein each said sub-memory array includes a first memory cell and a second memory cell, and wherein, said first memory cell is connected with said first bit line and said first common source line, and wherein said second memory cell is connected with said first bit line and said second common source line, and wherein said first memory cell and said second memory cell are symmetrically arranged at an identical side of said first bit line, and wherein each of said first memory cell and said second memory cell has an N-type field-effect transistor (FET) built in a P-type substrate or a P-type well region, and wherein said first memory cell and said second memory cell are both operation memory cells, in selecting one of said operation memory cells as a selected memory cell in carrying out operations, said operation memory cells, that are connected to said same bit line connecting to said selected memory cell, but not connected to said same common source line connecting to said selected memory cell, are referred to as a plurality of common bit memory cells; and said operation memory cells, that are connected to said same bit line connecting to said selected memory cell, are referred to as a plurality of common word memory cells; and rest of said operation memory cells are referred to a plurality of unselected memory cells, said method includes following steps of:
applying a substrate voltage V_{subp} on said P-type, substrate or said P-type well region connecting to said selected memory cell;
applying a first bit voltage V_{b1} and a first common source voltage Vₛ₁ respectively on said bit line and said common source line, all connecting to said selected memory cell;
applying a second common source voltage Vₛ₂ on said common source line connecting to each said common bit memory cell;
applying a second bit voltage V_{b2}, said first common source voltage Vₛ₁ respectively on said bit line and said common source line, both connecting to each said common word memory cell; and
applying said second bit voltage V_{b2} and said second common source voltage Vₛ₂ respectively on said bit line and said common source line, all connecting to each said unselected memory cell;
wherein when erasing data from said selected memory cell, following conditions are satisfied:
V_{subp} is grounded (0), V_{b1} is grounded (0), and Vₛ₁=HV (High Voltage);
wherein when writing data into said selected memory cell, following conditions are satisfied:
V_{subp} is grounded (0), V_{b1}=MV (medium voltage)−6V and Vₛ₁ is grounded (0);
wherein when reading data from said selected memory cell, following conditions are satisfied:
V_{subp} is grounded (0), V_{b1}=LV (Low Voltage)−2V, and Vₛ₁ is grounded (0);
wherein when erasing data from said unselected memory cell, following conditions are satisfied:
V_{subp} is grounded (0), V_{b2} is grounded (0), and Vₛ₂=LV (Low Voltage)−2V;
wherein when writing data into said unselected memory cell, following conditions are satisfied:
V_{subp} is grounded (0), V_{b2} is grounded (0), and Vₛ₂=LV (Low Voltage)˜2V: and
wherein when reading data from said unselected memory cell, following conditions are satisfied:
V_{subp} is grounded (0), V_{b2} is grounded (0), and Vₛ₂=LV (Low Voltage)—2V.

7. The operating method for a single-gate multiple-time programming non-volatile memory array according to claim 6, wherein said first memory cell comprising:
a transistor disposed in a semiconductor substrate and having a first dielectric layer, a first conduction gate and a plurality of ion-doped regions, wherein said first dielectric layer is disposed, on a surface of said semiconductor substrate, said first conduction gate is stacked on said first dielectric layer, and said ion-doped regions are respectively disposed at two sides of said first conduction gate to function as a source and a drain and disposed in said semiconductor substrate, wherein the source and the drain have different widths; and
a capacitor disposed on said semiconductor substrate, wherein an edge of the drain is served as a capacitor to control a floating gate and the capacitor includes a lightly-doped region between the drain and the floating gate, and said lightly-doped region and said ion-doped regions are doped with the same type of ions, and forming a single floating gate of said first memory cell.

8. The operating method for a single-gate multiple-time programming non-volatile memory array according to claim 6, wherein said second memory cell comprising:
a transistor disposed in a semiconductor substrate and having a first dielectric layer, a first conduction gate and a plurality of ion-doped regions, wherein said first dielectric layer is disposed on a surface of said semiconductor substrate, said first conduction gate is stacked on said first dielectric layer, and said ion-doped regions are respectively disposed at two sides of said first conduction gate to function as a source and a drain and disposed in said semiconductor substrate, wherein the source and the drain have different widths; and
a capacitor disposed on said semiconductor substrate, wherein an edge of the drain is served as a capacitor to control a floating gate and the capacitor includes a lightly-doped region between the drain and the floating gate, and said lightly-doped region and said ion-doped regions are doped with the same type of ions, and forming a single floating gate of said second memory cell.

9. An operating method of a single-gate multiple-time programming non-volatile memory array, wherein said non-volatile memory array includes a plurality of parallel bit lines having a first bit line, a plurality of parallel common source lines, being vertical to said bit lines and divided into a plurality of common source line groups including a first common source line group, including a first common source line and a second common source line, and a plurality of sub-memory arrays, each being connected with one of said bit lines and one of said common source line groups, and wherein each said sub-memory array includes a first memory cell and a second memory cell, and wherein said first memory cell is connected with said first bit line and said first common source line, and wherein said second memory cell is connected with said first bit line and said second common source line, and wherein said first memory cell and said second memory cell are symmetrically arranged at an identical side of said first bit line, and wherein each of said first memory cell and said second memory cell has an P-type field-effect transistor (FET) built in a N-type substrate or a N-type well region, and wherein said first memory cell and said second memory cell are both operation memory cells, in selecting one of said operation memory cells as a selected memory cell in carrying out operations, said operation memory cells, that are connected to said same bit line connecting to said selected memory cell, but not connected to said same common source line connecting to said selected memory cell, are referred to as a plurality of common bit memory cells: and said operation memory cells, that are connected to said same bit line connecting to said selected memory cell, are referred to as a plurality of common word memory cells; and rest of said operation memory cells are referred to a plurality of unselected memory cells, said method includes following steps of:
applying a substrate voltage V_{subn} on said N-type substrate or said N-type well region connecting to said selected memory cell;
applying a first bit voltage V_{b1} and a first common source voltage Vₛ₁ respectively on said bit line and said common source line, all connecting to said selected memory cell;
applying a second common source voltage Vₛ₂ on said common source line connecting to each said common bit memory cell;
applying a second bit voltage V_{b2}, said first common source voltage Vₛ₁ respectively on said bit line and said common source line, both connecting to each said common word memory cell; and
applying said second bit voltage V_{b2} and said second common source voltage Vₛ₂ respectively on said bit line and said common source line, all connecting to each said unselected memory cell;
wherein when erasing data from said selected memory cell, following conditions are satisfied;
V_{subn}=HV (High Voltage), V_{b1}=HV (High Voltage), and Vₛ₁ is grounded (0);
wherein when writing data into said selected memory cell, following conditions are satisfied:
V_{subn}=HV (High Voltage), V^{b1} is grounded (0), and Vₛ₁=MV (medium voltage)−6V;
wherein when reading data from said selected memory cell, following conditions are satisfied:
V_{subn}=HV (High Voltage), V_{b1} is grounded (0), and Vₛ₁=LV (Low Voltage)−2V;
wherein when erasing data from said unselected memory cell, following conditions are satisfied:
V_{subn}=HV (High Voltage), V_{b2}=LV (Low Voltage)−2V, and Vₛ₂=LV (Low Voltage) or grounded (0);
wherein when writing data into said unselected memory cell, following conditions are satisfied:
V_{subn}=HV (High Voltage), V_{b2}=LV (Low Voltage)−2V, and Vₛ₂=LV (Low Voltage) or grounded (0); and
wherein when reading data from said unselected memory cell, following conditions are satisfied:
V_{subn}=HV (High Voltage), V_{b2}=LV (Low Voltage)−2V, and Vₛ₂=LV (Low Voltage) or grounded (0).

10. The operating method for a single-gate multiple-time programming non-volatile memory array according to claim 9, wherein said first memory cell comprising:
a transistor disposed in a semiconductor substrate and having a first dielectric layer, a first conduction gate and a plurality of ion-doped regions, wherein said first dielectric layer is disposed on a surface of said semiconductor substrate, said first conduction gate is stacked on said first dielectric layer, and said ion-doped regions are respectively disposed at two sides of said first conduction gate to function as a source and a drain and disposed in said semiconductor substrate, wherein the source and the drain have different widths; and
a capacitor disposed on said semiconductor substrate, wherein an edge of the drain is served as a capacitor to control a floating gate and the capacitor includes a lightly-doped region between the drain and the floating gate, and said lightly-doped region and said ion-doped regions are doped with the same type of ions, and forming a single floating gate of said first memory cell.

11. The operating method for a single-gate multiple-time programming non-volatile memory array according to claim 9, wherein said second memory cell comprising:
a transistor disposed in a semiconductor substrate and having a first dielectric layer, a first conduction gate and a plurality of ion-doped regions, wherein said first dielectric layer is disposed on a surface of said semiconductor substrate, said first conduction gate is stacked on said first dielectric layer, and said ion-doped regions are respectively disposed at two sides of said first conduction gate to function as a source and a drain and disposed in said semiconductor substrate, wherein the source and the drain have different widths: and
a capacitor disposed on said semiconductor substrate, wherein an edge of the drain is served as a capacitor to control a floating gate and the capacitor includes a lightly-doped region between the drain and the floating gate, and said lightly-doped region and said ion-doped regions are doped with the same type of ions, and forming a single floating gate of said second memory cell.
